(19) United States
(12) Patent Application Publication
(10) Pub. No.: US 2013/0255745 A1
(43) Pub. Date: Oct. 3, 2013

(54) THIN LAYERED SOLAR MODULE HAVING A COMPOSITE WAFER STRUCTURE

(71) Applicants: Matthias Doech, Muenchen (DE); Walter Stetter, Illertissen (DE)

(72) Inventors: Matthias Doech, Muenchen (DE); Walter Stetter, Illertissen (DE)

(21) Appl. No.: 13/878,186

(22) PCT Filed: Oct. 11, 2011
(86) PCT No.: PCT/EP2011/067700

§ 371 Date: Jun. 24, 2013

(30) Foreign Application Priority Data
Oct. 12, 2010 (EP) 10187214.1

(51) Int. Cl. H01L 31/0216

(52) U.S. Cl. CPC H01L 31/02167
USPC 136/244; 438/80

(57) ABSTRACT

A thin layered solar module having a plurality of serially connected thin layer solar cells for producing photovoltaic energy is described. The module has two substrates which are interconnected by an adhesive layer. Each solar cell has a layer structure arranged between the two substrates, having a first electrode layer, a second electrode layer and a semi-conductor layer which is arranged between both electrode layers. The semi-conductor layer forms a pn-junction and is doped with a doping material. The adhesive layer has a certain amount of doping material such that the doping material from the semi-conductor layer is prevented from diffusing into the adhesive layer.

The invention relates generically to a thin-film solar module with a laminate sheet structure.

Photovoltaic layer systems for the direct conversion of sunlight into electrical energy are sufficiently well known. The materials and the arrangement of the layers are coordinated such that incident light radiation is converted directly into electrical current by one or a plurality of semiconducting layers with the highest possible radiation yield. Photovoltaic layer systems are referred to as “solar cells”. Photovoltaic layer systems with thicknesses of only a few microns that require carrier substrates to provide adequate mechanical strength are referred to by the term “thin-film solar cells”.

With respect to efficiency, thin-film solar cells based on polycrystalline chalcopyrite semiconductors have proved to be advantageous, with, in particular, copper indium diselenide (CuInSe₂ or CIS) distinguished by a particularly high absorption coefficient because of its band gap suited to the spectrum of sunlight.

Known carrier substrates for thin-film solar cells contain inorganic glass, polymers, or metal alloys, and can, depending on layer thickness and material properties, be implemented as rigid plates or flexible films. Because of the adequately available carrier substrates and a simple monolithic integration, large-area arrangements of thin-film solar cells can be produced economically.

Since, as a rule, with individual solar cells, only voltage levels of less than 1 volt can be obtained, many solar cells are usually connected serially in a solar module in order to thus obtain a technically useful output voltage. For this, thin-film solar modules offer the particular advantage that the thin-film solar cells can already be serially connected in an integrated form during production of the films.

The solar modules must be lastingly protected against environmental influences. Customarily, for this purpose, low-iron soda-lime glasses and adhesion-promoting polymer films are combined with the solar cells to form a weather-resistant solar module. The adhesive-promoting polymer films include, for example, polyvinyl butyral (PVB), ethylene vinyl acetate (EVA), polyethylene (PE), polyethylene acryl copolymer, or polyacrylamide (PA). Adhesion-promoting polymer films with ionic polymers are known, for example, from the publications U.S. Pat. No. 5,476,553 and WO 2009/149000.

The object of the present invention consists in advantageously improving conventional thin-film solar modules of the type in question, in particular, by reducing power output losses caused by aging and weather with comparatively lower production costs. These and other objects are accomplished according to the proposal of the invention by means of a thin-film solar module with the characteristics of the independent patent claim. Advantageous embodiments of the invention are indicated through the characteristics of the subclaims.

According to the invention, a thin-film solar module with laminate sheet structure is presented. The thin-film solar module has a plurality of thin-film solar cells for photovoltaic energy production, which are serially connected to each other, preferably in an integrated form.

Generically, the thin-film solar module comprises two substrates fixedly bonded to each other by an adhesive layer (encapsulation material). Each solar cell has a layer structure disposed between the two substrates, which has a first electrode layer, a second electrode layer, and at least one semiconductor layer disposed between the two electrode layers. It is understood that this list of layers is in no way complete, but rather, that the layer structure can also include other layers. Moreover, each layer can comprise one or a plurality of individual layers. By means of the layer structure of the solar cells, a heterojunction or pn-junction, in other words, a sequence of layers with a different conductor type, is formed. As is customary, the semiconductor layer is doped with a dopant, usually metal ions. Preferably the semiconductor layer is made of a chalcopyrite compound, which can, in particular, be a I-III-VI-semiconductor from the group copper-indium/gallium disulfur/diselenide (Cu(In,Ga)(S,Se)₂), for example, copper indium diselenide (CuInSe₂ or CIS), or related compounds. The doping is preferably done with sodium, potassium, and/or lithium, with the dopant present in the semiconductor layer in ionic form. The sodium, potassium, or lithium doping results in an intrinsic doping of the copper-indium/gallium disulfur/diselenide (Cu(In,Ga)(S,Se)₂) through formation of intrinsic defects.

It is essential that the adhesive layer that bonds the two substrates to each other have the dopant used for doping the semiconductor layer (usually metal ions) in such an amount that diffusion of the dopant from the semiconductor layer into the adhesive layer is prevented.

As experiments of the applicant surprisingly demonstrated, diffusion of the charged dopant from the semiconductor layer into the adhesive layer can at least be reduced if the dopant is contained in the adhesive layer in at least a specific minimum concentration. Thus, advantageously, the long-term stability of the solar module can be improved and a power output loss due to a reduced dopant concentration in the semiconductor layer caused by aging can be counteracted.

The outward diffusion of the charged dopant from the semiconductor layer is always associated with an inward diffusion of a charged particle of the same charge type such that in the diffusion process a substitution between ions of the same charge ultimately occurs. When the adhesive layer contains the dopant used for doping the semiconductor layer in an amount sufficient for the desired function, the dopant concentration of the semiconductor layer either does not change or at least not in such a way that a substantial power output loss due to aging occurs.

In an advantageous embodiment of the thin-film solar module according to the invention, the adhesive layer bonding the two substrates to each other is made of a material that consists of or at least includes a compound that contains, ionically bonded, the dopant used for doping the semiconductor layer. Thus, the ions of the dopant of the adhesive layer are suitably available as diffusion partners for the same kind of ions of the semiconductor layer. Preferably, for this purpose, the material of the adhesive layer is or includes an adhesion-promoting polymer layer, in particular an ionic polymer (ionomer), which is easy to handle and can be used economically in industrial series production.

The partial or total exchange of ions of the ionomer by the ions used for doping the semiconductor layer can be carried out chemically in a simple manner such that the concentration of the dopant in the adhesive layer can be adjusted easily and reliably. With the use of ionomers, it is preferable for the ionomer to have relatively long, nonionic alkylene chains. By means of these alkylene chains, the adhesive layer advantageously has, despite the ionic sections of the polymer, a relatively low electrical conductivity such that the electrically insulating property of the adhesive layer is not, or is only slightly affected by the ionic property of the ionomer.

The adhesive layer bonding the two substrates to each other preferably includes ionomers, i.e., organic polymers with ionic functional groups. The adhesive layer preferably includes copolymers and/or block copolymers of the formula A-B, where A represents linear or branched nonpolar hydrocarbon groups and B represents hydrocarbon groups with sodium-bonded acid groups. The expression “nonpolar hydrocarbon groups” includes, in the context of the invention, saturated and unsaturated hydrocarbon groups without polar functional groups. The expression “sodium-bonded acid groups” includes, in the context of the invention, organic acid groups whose acid protons are partially or completely substituted by sodium ions. The substitution of the acid protons can take place, for example, by reaction with sodium hydroxide.

In one possible embodiment, 20% to 90% of the acid protons are substituted by dopant ions, in particular, sodium ions, by means of which, advantageously, a particularly high stability of the semiconductor layer can be obtained. In another possible embodiment, less than 5% of the acid protons (but more than 0%) are substituted by dopant ions, in particular sodium ions, by means of which, advantageously, a particularly high adhesion of the adhesive layer to the two substrates can be obtained. This is true in particular for glass substrates, in the case of which hydrogen bonds can form between the acid protons of the adhesive layer and Si atoms of the substrates. It can be advantageous, in particular, for a relative share of the acid protons that are substituted by dopant ions, in particular sodium ions, to be in a range of 0.1% to less than 5%, in particular 1% to 4%, in particular 2% to 4%, in particular 3% to 4%. The above percentage data indicate the relative amount of the substituted acid protons based on the total amount of acid protons before the substitution. The percentage data thus correspond to a substitution level of the material of the adhesive layer.

The groups A and B can be present in the copolymer both alternatingly -A-B-A-B-A- and non-alternatingly, for example, in the sequence -A-A-B-A-B-B-B- or -A-A-A-A-A-B-B-B-B-. The adhesive layer preferably includes still other thermoplastic polymers such as polyolefins, polyethylene, polypropylene, polyacrylates, ethyl acrylate, methyl acrylate, polyvinyl alcohol, polyvinylacetate, polyvinyl acetyls, and/or polyamides. The adhesive layer includes preferably 5 to 30 wt.-% (weight percent) of copolymers of the formula A-B.

The adhesive layer preferably contains copolymers of the general formula A-B=—[(CH₂—CHR₁)ₙ—((R₃—)C(—R₂)(—CH₂))ₘ, where
R₁═H, CH₃, or CH₂—CH₃,
R₂═—COONa, —CH₂—COONa, SO₃Na, or —H₂CSNa, and
3R₃═H, CH₃, CH₂—CH₃, or phenyl.

The letters n and m correspond to numbers ≧5, preferably ≧10, particularly preferably ≧25, and can assume the same or different values. Within the context of polymer molecular weight distribution, averaged, non-integer values of n and m are possible. The production of the copolymers according to the invention can take place, for example, through copolymerization of ethylene and methacrylic acid. It can be advantageous for the adhesive layer to contain copolymers in which exclusively —H₂CSNa is contained as radicals R₂.

The copolymers of the formula A-B include the component B preferably in an amount of 5 to 30 wt.-% of the component B, particularly preferably in an amount of 10 to 20 wt.-%.

Additionally or alternatively, the charged dopant can be absorbed, for example, at least on one surface (alternatively on both surfaces) of the adhesive layer facing the semiconductor layer. By means of this measure, the absorbed ions can particularly effectively counteract a reduction in the concentration of the dopant in the semiconductor layer. An adhesive film for bonding the two substrates by fusion with a temperature increase can be provided particularly easily and economically with adsorbed dopant ions in industrial series production. For this, it suffices to dip the adhesive film into an appropriate immersion bath with a solution containing the dopant. Alternatively, it would also be conceivable to spray the adhesive film with this solution. In the context of the present invention, the term “adsorption” means adhesion of the dopant on the surfaces of the adhesive film, regardless of the nature of the bonding of the dopant to the surfaces. In particular, bonding mechanisms that are known in the art in the context of “chemical adsorption” or “physical adsorption” should be included. Generally, the concentration of the dopant that must be contained in the adhesive layer to inhibit the outward diffusion of the dopant depends on the concentration of the dopant in the semiconductor layer. Typically, in the case of a sodium-ion-doped chalcopyrite semiconductor of the group copper-indium/gallium-disulfur/diselenide (Cu(In,Ga)(S,Se)₂), there is a surface density in the range from 200-1000 ng/cm². In particular, for this case, it is preferable for the relative amount of the metal ions contained in the adhesive layer in terms of the total material of the adhesive layer to be in a range from 0.1 to 4 wt.-%, more preferably in a range from 0.5 to 2 wt.-%, and even more preferably in a range from 1 to 2 wt.-%. The metal ions can be contained in the adhesive layer, for example, in a range from more than 1.5 wt.-% to 2 wt.-%, in particular 1.6 wt.-% to 2 wt.-%. The percentage data here are based on the total weight of the material contained in the adhesive layer. As experiments of the applicant have shown, outward diffusion of the metal ions used for doping from the semiconductor layer can be satisfactorily counteracted with such a content of metal ions in the adhesive layer. As already indicated above, it can be advantageous, in particular with regard to the adhesion of the adhesive layer to the two substrates, for the relative amount of the dopant ions, in particular metal ions, based on the total quantity of acidic protons before the substitution, to be less than 5% (but more than 0%).

In another advantageous embodiment of the thin-film solar module according to the invention, the adhesive layer is ionically and/or covalently bonded to the layers adjacent to or contacting the adhesive layer. By means of this measure, in particular by covalent bonding between the adhesive layer and the adjacent layers, a further improvement of the long-term stability of the thin-film solar module can be obtained through inhibition of the entry of water into the semiconductor layer. Since hydrogen ions are made available as exchange partners by the water molecules, outward diffusion of metal ions that is caused by water present in the thin-film solar module is counteracted by the proposed measure. The long-term stability of the thin-film solar module can thus be even further improved.

A covalent bonding between the adhesive layer and the layers contacting it can preferably be obtained such that the adhesive layer has a compound that can form inorganic hybrid compounds with the materials of the layers adjacent to or contacting the adhesive layer. For this purpose, the adhesive layer can include, for example, alkyl silanes or alkylalanes in a suitable amount. This compound can, for example, be admixed with the material of the adhesive layer. Alternatively, a layer made of this compound can be disposed, in each case, between the adhesive layer and the layers adjacent to or contacting the adhesive layer.

In another advantageous embodiment of the thin-film solar module according to the invention, the adhesive layer has a water content of less than 0.1% or is completely free of water. Through this measure as well, the long-term stability of the thin-film solar module is even further improved by inhibition of the outward diffusion of metal ions from the semiconductor layer by means of a reduction of the quantity of possible exchange partners (hydrogen ions).

Ionomer films according to the prior art used as an adhesive layer have a certain proportion of zinc to lower the moisture content, as is known, for example, from WO 02/103809 A1. As experiments of the applicant with a so-called “dry heat aging test” surprisingly showed, the efficiency of Cu(In,Ga)(S,Se)₂ thin-film solar cells with adhesive layers with a zinc content of 0.7 wt.-% is clearly reduced at a temperature of 85° C. This can be explained by ion exchange of zinc out of the adhesive layer and sodium, potassium, and/or lithium in the Cu(In,Ga)(S,Se)₂ layer. The ion exchange is accelerated by the increased temperature and the intrinsic defect structure of the absorber is severely disrupted.

In another advantageous embodiment of the thin-film solar module according to the invention, a circumferential edge gap between the two substrates is sealed with a sealing material serving as a barrier against water. Through this measure as well, the long-term stability of the thin-film solar cell can be even further improved by inhibition of the outward diffusion of metal ions out of the semiconductor layer by a reduction in the quantity of water molecules by means of which a possible exchange partner (hydrogen ions) for the metal ions in the semiconductor layer is made available. Advantageously, the sealing material is implemented such that it can bind water chemically (e.g., by calcium carbonate CaO) and/or physically (e.g., by zeolites). A substantial advantage of such a sealing material results from the fact that it serves as a sink for water molecules and can thus attract and bind water even in the edge region between the two substrates in order to thus reduce the water content in the thin-film solar module.

In another advantageous embodiment of the thin-film solar module according to the invention, the first electrode layer is implemented in the form of a transparent front electrode layer and the second electrode layer is implemented as an opaque back electrode layer. Preferably, a barrier layer impermeable to the dopant, in particular metal ions, is disposed between a substrate disposed on a side of the back electrode layer facing away from the front electrode layer and the back electrode layer. Through this measure as well, the long-term stability of the thin-film solar module can be even further improved.

The invention further extends to a method for producing a thin-film solar module. The method comprises a step in which two substrates are provided with a layer structure disposed between the two substrates. The layer structure comprises a first electrode layer, a second electrode layer, and at least one semiconductor layer disposed between the two electrode layers, with the semiconductor layer forming a pn-junction and doped with a dopant. The method includes another step in which the two substrates are bonded by an adhesive layer under the action of heat, vacuum, and/or pressure. The adhesive layer used has the dopant of the semiconductor layer in such an amount that diffusion of the dopant from the semiconductor layer into the adhesive layer is prevented.

The bonding of the thin-film solar module takes place, for example, with lamination methods known per se, for example, with autoclave processes or vacuum methods, such that no detailed explanation is needed here.

The invention further extends to the use of an adhesive layer in a thin-film solar module as described above with the adhesive layer having the dopant contained in the semiconductor layer of the thin-film solar module in such an amount that diffusion of the dopant from the doped semiconductor layer into the adhesive layer is prevented.

In addition, the invention extends to the use of an adhesive layer with a sodium content of 0.1 to 4 wt.-% in a thin-film solar module as described above with a sodium-doped semiconductor layer, in particular a sodium-doped Cu(In,Ga)(S,Se)₂ layer. By means of the sodium content of the adhesive layer, the diffusion of sodium from the sodium-doped semiconductor layer into the adhesive layer is prevented.

The invention also extends to the use of an adhesive layer in a thin-film solar module as described above which contains ionomers, in particular copolymers of the formula A-B, where A represents nonpolar hydrocarbon groups and B represents hydrocarbon groups with sodium-bound organic acid groups. These copolymers of the formula A-B can, in particular, contain the following groups: A=—(CH₂—CHR₁)ₙ and B=—((R₃—)C(—R₂)(—CH₂))ₘ, with R₁═H, CH₃, or CH₂—CH₃; R₂═COONa, —CH₂—COONa, SO₃Na, or —H₂CSNa; R₃═H, CH₃, CH₂—CH₃, or phenyl, where n, m>10. In addition, the copolymers of formula A-B can contain the component B in particular in an amount of 5 to 30 wt.-%, in particular 10 to 20 wt.-%. Moreover, a relative amount of the acidic protons of the ionomers that were substituted by the dopant, based on the total amount of acidic protons before the exchange with the dopant, can be, in particular, less than 5% (but more than 0%).

### BRIEF DESCRIPTION OF THE DRAWINGS

The invention is now explained in detail using an exemplary embodiment, with reference to the accompanying figures. They depict:

FIG. 1 a schematic cross-sectional view of an exemplary embodiment of the thin-film solar cell according to the invention, and

FIG. 2 a schematic cross-sectional view of an exemplary embodiment of the thin-film solar module according to the invention with two serially connected thin-film solar cells.

### DETAILED DESCRIPTION OF THE DRAWINGS

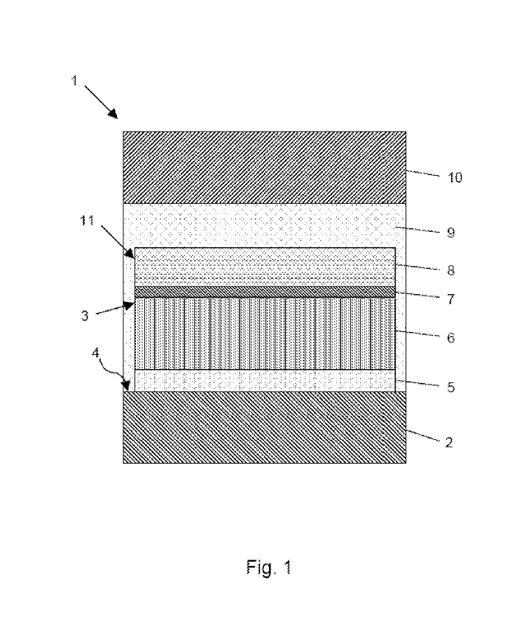

FIG. 1 illustrates a thin-film solar module generally referenced to with the reference character 1. The thin-film solar module 1 comprises a plurality of solar cells 11 serially connected in an integrated form, with, for the sake of a simpler depiction, only a single thin-film solar cell 11 shown in FIG. 1.

According to it, the thin-film solar module 1 has a structure corresponding to the so-called “substrate configuration”, in other words, it has an electrically insulating first substrate 2 with a layer structure 3 made of thin layers applied thereon, with the layer structure 3 disposed on a light-incident-side surface 4 of the first substrate 2. The first substrate 2 is made here, for example, of glass with a relatively low light transmittance, with it equally possible to use other electrically insulating materials with desired strength and inert behavior relative to the process steps performed.

The layer structure 3 comprises a back electrode layer 5 disposed on the surface 4 of the first substrate 2, which is made, for example, from an opaque metal such as molybdenum (Mo) and can, for example, be applied on the first substrate 2 by vapor deposition or by magnetic field-assisted cathode sputtering. The back electrode layer 5 has a layer thickness of 300 nm to 600 nm, which amounts, for example, to 500 nm. A photovoltaically active semiconductor layer or absorber layer 6 made of a semiconductor doped with metal ions, whose band gap is preferably capable of absorbing the greatest possible share of sunlight, is deposited on the back electrode layer 5. The absorber layer 6 is made, for example, of a p-conducting chalcopyrite semiconductor, for example, of a compound of the group Cu(In,Ga)(S,Se)₂, in particular sodium (Na)-doped Cu(In,Ga)(S,Se)₂. The absorber layer 6 has, for example, a layer thickness in the range from 1-5 μm and is, for example, ca. 2 μm. A barrier layer (not shown in detail in FIG. 1) that acts as a diffusion barrier for the metal ions of the absorber layer serving as a dopant can be provided between the back electrode layer 5 and the absorber layer 6. The barrier layer includes, for example, silicon nitride.

A buffer layer 7 (not shown in detail in FIG. 1), which consists here, for example, of a single layer of cadmium sulfide (CdS) and a single layer of intrinsic zinc oxide (i-ZnO), is deposited on the absorber layer 6.

A front electrode layer 8 is applied, for example, by vapor deposition, on the buffer layer 7. The front electrode layer 8 is transparent to radiation in the visible spectral range (“window electrode”) such that the incident sunlight is only slightly weakened. The transparent front electrode layer 8 is based, for example, on a doped metal oxide, for example, n-conductive, aluminum (Al)-doped zinc oxide (ZnO). Such a front electrode layer 8 is generally referred to as a TCO layer (TCO=transparent conductive oxide). Via the front electrode layer 8, together with the buffer layer 7 and the absorber layer 6, a heterojunction (i.e., a sequence of layers of the opposing conductor type) is formed. The buffer layer 7 can effect an electronic adaptation between the semiconductor material of the absorber layer 6 and the material of the front electrode layer 8. The layer thickness of the front electrode layer 8 is, for example, about 500 nm.

For protection against environmental influences, an adhesive layer 9, made, for example, of an ionomer, and which serves to encapsulate the layer structure 3, is applied on the front electrode layer 8.

In addition, the layer structure 3 is provided with a second substrate 10 transparent to sunlight, which is, for example, made of extra white glass with low iron content, with it equally possible to use other electrically insulating materials with desired strength and inert behavior relative to the process steps performed. The second substrate 10 serves to seal the layer structure 3.

The first substrate 2 and the second substrate 10 are fixedly bonded to each other by the adhesive layer 9. Here, for example, the adhesive layer 9 is a thermoplastic adhesive layer that is plastically deformable by heating and, upon cooling, fixedly bonds the two substrates 2 and 10 to each other.

In the thin-film solar module 1, the adhesive layer 9 has the same metal ions as the absorber layer 6, which are used there as a dopant. For this purpose, the adhesive layer 9 contains, for example, a certain amount of an ionic polymer, here, for example, polyethylene co-methacrylic acid, in which the hydrogen ions were at least partially substituted by the metal ions of the absorber layer 6 serving as dopant, here, for example, sodium ions. For a surface density of sodium ions as dopant in the range from 200-1000 ng/cm² with an absorber layer 6 comprising a semiconductor of the group copper-indium/gallium disulfur/diselenide (Cu(In,Ga)(S,Se)₂), the relative amount of sodium ions contained in the adhesive layer 9 based on the total material of the adhesive layer 9 is in a range from 1 wt.-% to 2 wt.-%. In particular, the relative amount of sodium ions contained in the adhesive layer 9, based on the total amount of acidic protons before the substitution by sodium ions, can be less than 5% (but more than 0%), to obtain, on the one hand, a particularly high adhesion to the two substrates 2, 10 and, on the other, adequate practical inhibition of the outward diffusion of sodium ions from the absorber layer 6.

The use of polyethylene co-methacrylic acid has the advantage that the acid has long nonionic ethylene chains such that the electrically insulating property of the adhesive layer 9 is only slightly affected by the isomer.

Alternatively, the adhesive layer 9 could be formed, for example, by an adhesive film which, before introduction into the layer structure 3 and fusing to form the adhesive layer 9, is drawn through a sodium chloride bath in order to adsorb sodium ions on its surfaces. For example, sodium ions are adsorbed only on the surface facing the absorber layer 6. By means of the content of sodium ions in or on the adhesive layer 9, outward diffusion of the sodium ions from the absorber layer 6 into the adhesive layer 9 can be effectively counteracted. The adsorption of the sodium ions on the adhesive film has process technology advantages since it can be very easily and economically incorporated into the production of thin-film solar modules.

In addition, the adhesive layer 9 contains a certain amount of a compound that results in the fact that the material of the adhesive layer 9 can enter into covalent bonds with the materials of the adjacent layers, in this case, the second substrate 10 and the front electrode layer 8. For example, a compound that can form inorganic hybrid compounds with the materials of the adjacent layers, for example, alkyl silanes or alkylalanes, is admixed with the material of the adhesive layer 9. Alternatively, it would also be conceivable for a layer made of this compound to be disposed in each case between the adhesive layer 9 and the front electrode layer 8 or the second substrate 10. By this means, a further improvement of the long-term stability of the thin-film solar module 1 can be achieved through inhibition of the entry of water molecules into the absorber layer 6.

Although not depicted in detail in FIG. 1, a circumferential edge gap between the two substrates 2 and 10 is sealed with a sealing material serving as a barrier against water, in this case, for example, poly-isobutylene (PIB), to further improve the long-term stability of the thin-film solar module 1 by inhibition of the entry of water. The sealing material is additionally provided with at least one compound to bind water molecules chemically and/or physically.

The thin-film solar module 1 can be produced easily and economically in industrial series production, with the various layers of the layer structure 3 being deposited on the first substrate 2 and structured using a suitable structuring technology such as laser writing and mechanical processing, for example, by drossing or scratching. Such structuring typically comprises three structuring steps for each solar cell which need not be explained in detail here.

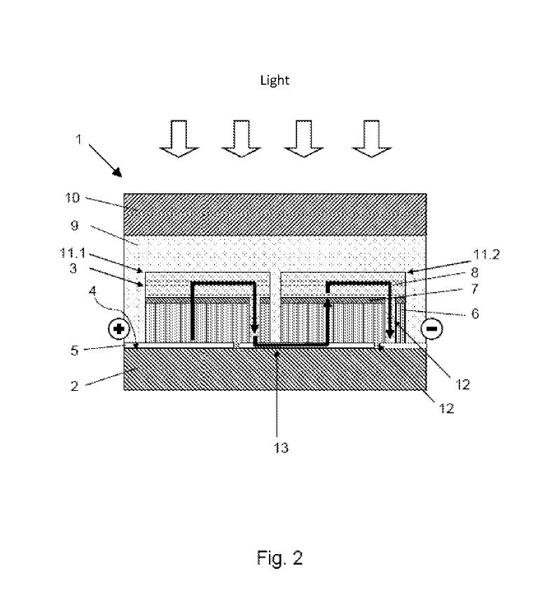

FIG. 2 depicts two thin-film solar cells 11.1 and 11.2 of a thin-film solar module 1 that are serially connected to each other. The division into the individual thin-film solar cells 11.1 and 11.2 occurs by means of incisions 12 using a suitable structuring technology, such as laser writing and mechanical processing, for example, by drossing or scratching. The individual solar cells 11.1 and 11.2 are serially connected to each other via a coating region 13 of the back electrode layer 5.

A thin-film solar module 1 according to the invention has, for example, 100 serially connected thin-film solar cells and an open-circuit voltage of 56 volt. In the example depicted here, both the resultant positive (+) and the resultant negative power connection (−) of the thin-film solar module 1 is guided through the back electrode layer 5 and electrical contact is made there.

The present invention makes available a thin-film solar module whose long-term stability is improved, wherein aging-related, irreversible power output losses due to degradation of the absorber layer 6 can be counteracted. This can be achieved, on the one hand, by the fact that a migration of mobile ions out of the absorber layer 6 is at least largely prevented in that the adhesive layer 9 is saturated with the mobile ions such that it does not act as a sink for the mobile ions. On the other hand, hydrolysis of the absorber layer 6 triggered by water present in the thin-film solar module 1 can be counteracted. It is thus avoided that hydrolysis products in the structuring trenches result in disadvantageous electrical resistances. In addition, it is possible to prevent moisture from increasing the parallel electrical resistance of the solar cells.

As aging tests of the applicant have demonstrated, the customary losses in efficiency with sodium-doped Cu(In,Ga)(S,Se)₂ thin-film solar modules are clearly reduced by means of the measures identified.

As shown in Table 1, sodium-doped Cu(In,Ga)(S,Se)₂ thin-film solar modules with three different adhesive layers (film 1-3) were investigated. In the tests, the loss of efficiency of the thin-film solar module was measured using a dry heat aging test known to the person skilled in the art. The dry heat aging test was performed at a temperature of 85° C. and and a relative humidity of <25% over a period of 5000 h (hours). The sodium content and zinc content of the adhesive layers was ascertained by means of x-ray fluorescence analysis. A sodium content or zinc content of 0 wt.-% in Table 1 indicates a content below the amount of <100 ppm detectable in the x-ray fluorescence analysis, based on the weight of the adhesive layer.

TABLE 1

| | | | | Loss of |
|---|---|---|---|---|
| | | | | efficiency |
| | | | | after dry |
| Adhesive | | Sodium/ | Zinc/ | heat aging |
| layer | Material | wt.-% | wt.-% | test |
| Film 1 | Ionomer | 1.5 | 0 | 4% |
| Film 2 | PVB | 0 | 0 | 10% |
| (comparative | | | | |
| example) | | | | |
| Film 3 | Ionomer | 0 | 0.7 | 40% |
| (comparative | | | | |
| example) | | | | |

Accordingly, film 2 showed, with a sodium content of 0 wt.-% and and a zinc content of 0 wt.-% after the dry heat aging test, a loss of efficiency of the thin-film solar module of 10%. Film 3, with a zinc content of 0.7 wt.-%, showed a loss of 40%. A film 1 used according to the invention, with a sodium content of 1.5 wt.-% and a zinc content of 0 wt.-%, surprisingly showed a loss of only 4%. This result was unexpected and surprising for the person skilled in the art.

### LIST OF REFERENCE CHARACTERS

1 thin-film solar module

2 first substrate

3 layer structure

4 surface

5 back electrode layer

6 absorber layer

7 buffer layer

8 front electrode layer

9 adhesive layer

10 second substrate

11, 11.1, 11.2 thin-film solar cell

12 division

13 layer region

1. A thin-film solar module for photovoltaic energy production, comprising:
two substrates bonded to each other by an adhesive layer, and
a plurality of serially connected thin-film solar cells, wherein
each thin-film solar cell has a layer structure disposed between the two substrates, comprising a first electrode layer, a second electrode layer, and at least one semiconductor layer disposed between the first and second electrode layer, wherein the at least one semiconductor layer forms a pn-junction and is doped with a dopant, with the adhesive layer having the dopant in such an amount that diffusion of the dopant from the at least one semiconductor layer into the adhesive layer is prevented.

2. The thin-film solar module according to claim 1, wherein the at least one semiconductor layer contains a chalcopyrite compound, in particular Cu(In,Ga)(S,Se)₂.

3. The thin-film solar module according to claim 1, wherein the at least one semiconductor layer contains, as dopant, sodium ions, potassium ions, or lithium ions.

4. The thin-film solar module according to claim 1, wherein the adhesive layer has the dopant in an amount of 0.1 to 4 wt.-% and in particular 0.5 to 2 wt.-%.

5. The thin-film solar module according to claim 1, wherein the adhesive layer is made of a compound ionically binding the dopant or includes such a compound.

6. The thin-film solar module according to claim 1, wherein the adhesive layer contains ionomers, in particular copolymers of the formula A-B, wherein A represents nonpolar hydrocarbon groups and B represents hydrocarbon groups with sodium-bonded organic acid groups.

7. The thin-film solar module according to claim 20, wherein:
A=—(CH₂—CHR₁)ₙ and B=—((R₃—)C(—R₂)(—CH₂))ₘ, where
R₁═H, CH₃, or CH₂—CH₃,
R₂═COONa, —CH₂—COONa, SO₃Na, or —H₂CSNa
R₃═H, CH₃, CH₂—CH₃, or phenyl, and
where n, m>10.

8. The thin-film solar module according to claim 20, wherein the copolymers of the formula A-B contain the component B in an amount of 5 to 30 wt-%, in particular 10 to 20 wt-%.

9. The thin-film solar module according to claim 6, wherein a relative amount of acidic protons of the ionomers, which were substituted by the dopant, based on a total amount of acidic protons before the substitution with the dopant, is less than 5%.

10. The thin-film solar module according to claim 1, wherein the dopant is adsorbed at least on one surface of the adhesive layer facing the semiconductor layer.

11. The thin-film solar module according to claim 1, wherein the adhesive layer has a water content of less than 0.1%.

12. The thin-film solar module according to claim 1, wherein a circumferential edge gap between the two substrates is sealed with a sealing material serving as a barrier against water.

13. The thin-film solar module according to claim 12, wherein the sealing material is implemented such that it can bind water chemically and/or physically.

14. The thin-film solar module according to claim 1, wherein the first electrode layer is a transparent front electrode layer, the second electrode layer is an opaque back electrode layer, and a barrier layer, impermeable to the dopant, is disposed between a substrate of the two substrates disposed on a side of the opaque back electrode layer facing away from the transparent front electrode layer and the opaque back electrode layer.

15. A method for producing the thin-film solar module according to claim 1, comprising:
providing two substrates with a layer structure disposed between the two substrates, comprising a first electrode layer, a second electrode layer, and at least one semiconductor layer disposed between the first and second electrode layer, the at least one semiconductor layer forms a pn-junction and is doped with a dopant,
bonding the two substrates with an adhesive layer under an action of heat, vacuum, and/or pressure, with the adhesive layer having the dopant of the semiconductor layer in an amount such that diffusion of the dopant from the semiconductor layer into the adhesive layer is prevented.

16. The method according to claim 15, further comprising:
using the adhesive layer in the thin-film solar module, the adhesive layer has a dopant in an amount such that the diffusion of the dopant from a doped semiconductor layer into the adhesive layer is prevented.

17. The method according to claim 15, further comprising:
using the adhesive layer with a sodium content of 0.1 to 4 wt.-% in a thin-film solar module for prevention of the diffusion of sodium out of a sodium-doped semiconductor layer, in particular out of a sodium-doped Cu(In,Ga)(S,Se)₂ layer, into the adhesive layer.
